(19) United States
(12) Patent Application Publication
(10) Pub. No.: US 2012/0092044 A1
(43) Pub. Date: Apr. 19, 2012

(54) CIRCUIT FOR SWAPPING A MEMORY CARD IN AN ELECTRONIC DEVICE

(75) Inventor: Chien-Hsin Lien, Taipei (TW)

(73) Assignee: ABILITY ENTERPRISE CO., LTD., Taipei (TW)

(21) Appl. No.: 12/904,098

(22) Filed: Oct. 13, 2010

(51) Int. Cl. H03L 7/00; G06F 12/00; G06F 13/00

(52) U.S. Cl. 327/142; 710/302; 711/115; 711/E12.001

(57) ABSTRACT

A circuit for hot-swapping a memory card in an electronic device is disclosed. A power-reset unit has a first node electrically coupled to a power supply, and a second node electrically coupled to a power pin of the memory card. The power-reset unit is configured to generate a rising voltage at the second node without rebooting the electronic device when the memory card is hot-plugged into the electronic device.

### BACKGROUND OF THE INVENTION

1. Field of the Invention

The present invention generally relates to a memory card, and more particularly to a circuit for hot-swapping a memory card in an electronic device.

2. Description of Related Art

A memory card such as a secure digital (SD) card is an electronic device that can store digital data without power, and is commonly used in a variety of electronic devices such as a digital camera or a portal electronic device equipped with the digital camera.

It is not uncommon that users need to replace a full memory card with an empty memory card midway through picture taking. The replacement may be done by turning off the camera before unplugging the full memory card, followed by turning on the camera again after the empty memory card has been inserted. Nevertheless, such turning off and on of the camera takes a considerable amount of time, during which the camera, for example, moves its lens and stops/starts the procedure. As a result, some great scenes are oftentimes missed forever.

The off-the-shelf cameras nowadays do not provide hot-swapping (or hot-plugging and hot-unplugging) function. Accordingly, even though a hot-unplugged memory card does not suffer data loss, a hot-plugged memory card definitely cannot be detected by the camera. Some advanced cameras do indeed provide the hot-plugging function; however, these cameras reboot after the hot-plugged memory card is detected. Therefore, no significant time is saved in the cameras with hot-plugging function compared with the cameras without hot-plugging function.

For the reason that conventional cameras could not effectively and quickly reset a plugged-in memory card, a need has arisen to propose a novel scheme for hot-swapping a memory card without rebooting the camera.

### SUMMARY OF THE INVENTION

In view of the foregoing, it is an object of the embodiment of the present invention to provide a circuit for hot-swapping a memory card in an electronic device without rebooting the electronic device.

According to one embodiment, a power-reset unit has a first node electrically coupled to a power supply, and a second node electrically coupled to a power pin of the memory card. The power-reset unit is configured to generate a rising voltage at the second node without rebooting the electronic device when the memory card is hot-plugged into the electronic device.

### BRIEF DESCRIPTION OF THE DRAWINGS

FIG. 1 shows a block diagram of a memory system adaptable to an electronic device according to one embodiment of the present invention;

FIG. 2 shows a rising voltage during a ramp-up period;

FIG. 3A illustrates a first specific embodiment showing an SD card and an exemplary power-reset unit;

FIG. 3B shows some signal waveforms illustrating an operation of the first specific embodiment of FIG. 3A;

FIG. 3C shows some signal waveforms illustrating another operation of the first specific embodiment of FIG. 3A;

FIG. 4A illustrates a second specific embodiment showing an SD card and an exemplary power-reset unit; and

FIG. 4B shows some signal waveforms illustrating an operation of the second specific embodiment of FIG. 4A.

### DETAILED DESCRIPTION OF THE INVENTION

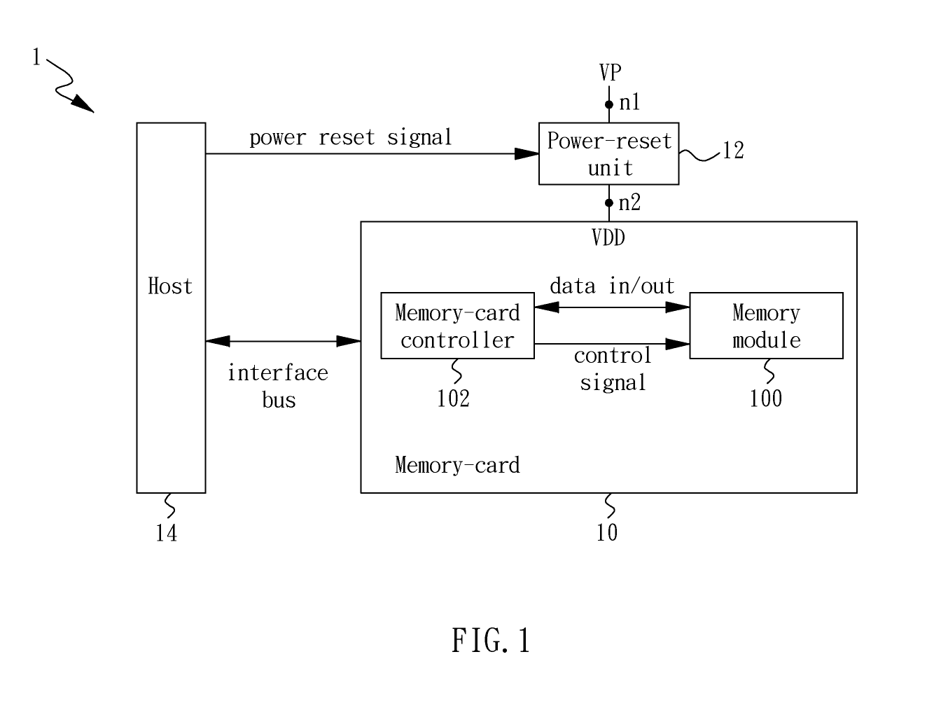

FIG. 1 shows a block diagram of a memory system 1 adaptable to an electronic device according to one embodiment of the present invention. The electronic device may be, but is not limited to, a digital camera, a digital camcorder, a computer, a personal digital assistant (PDA), a media player, or a mobile phone.

The memory system 1 includes a memory card 10, a power-reset unit 12, and a host 14. In the embodiment, the memory card 10 is particularly a non-volatile memory card (e.g., a flash memory card), such as a secure digital (SD) card, a secure digital high-capacity (SDHC) card, a secure digital extended-capacity (SDXC) card, or a multimedia card (MMC). Specifically speaking, the memory card 10 includes a memory module 100 and a memory-card controller (or “controller”) 102. The controller 102 controls data input and output to/from the memory module 100 using some control signals.

The power-reset unit 12 has a first node n1 that is electrically coupled to a power supply VP, and a second node n2 that is electrically coupled to a power pin VDD of the memory card 10. In this specification, the term “electrically coupled” indicates either that one electronic element (or node) is directly connected to another electronic element (or node), or that one electronic element (or node) is indirectly connected to another electronic element (or node) via one or more intermediate electronic elements.

The host 14, such as a computer, communicates with the memory card 10 via an interface bus such as a secure digital (SD) bus or a serial peripheral interface (SPI) bus. Further, the host 14 may control the power-reset unit 12 by a power reset signal.

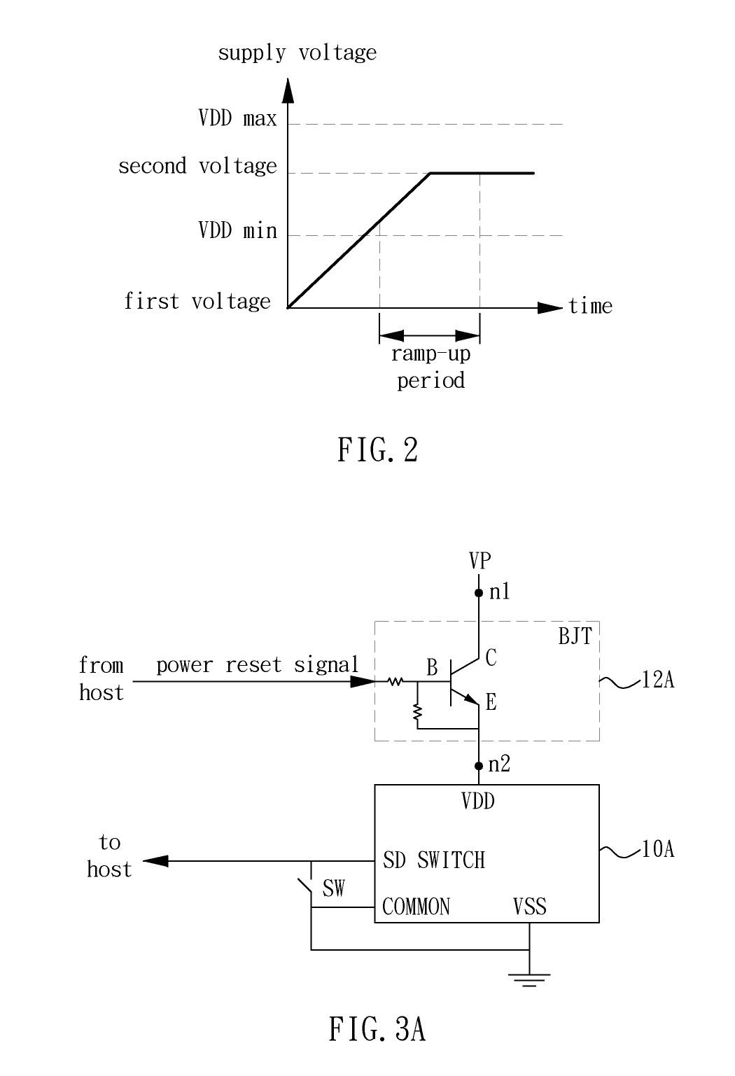

According to one aspect of the embodiment, the power-reset unit 12 is configured to generate a rising voltage (e.g., from a low-level voltage (first voltage) to a high-level voltage (second voltage)) at the second node n2 (i.e., the power pin VDD of the memory card 10) without rebooting the electronic device associated with the memory system 1 when the memory card 10 is hot-plugged into the electronic device. As shown in FIG. 2, the generated rising voltage is checked by the controller 102 to determine whether the first voltage (e.g., the low-level voltage) is lower than a predefined minimum voltage VDD min and the second voltage (e.g., the high-level voltage) is higher than a predefined maximum voltage VDD max during a ramp-up period. If the rising voltage satisfies such requirement (i.e., the rising voltage passes the check), the controller 102 will then initialize the memory module 100 after the ramp-up period. On the other hand, if the rising voltage does not satisfy the requirement within the specified ramp-up period (i.e., the rising voltage fails the check), the memory card 10 will then enter into (or stay at) an inactive state.

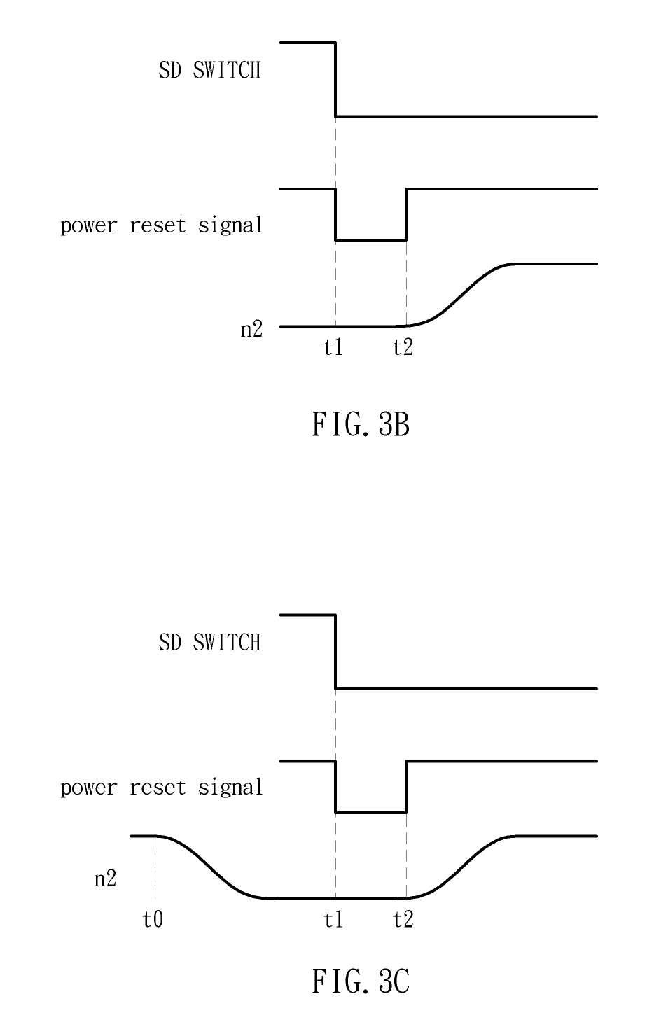

FIG. 3A illustrates a first specific embodiment showing an SD card 10A and an exemplary power-reset unit 12A. In the embodiment, the power-reset unit 12A includes a transistor such as a bipolar junction transistor (BJT). The BJT has a collector C electrically coupled to the first node n1, an emitter E electrically coupled to the second node n2, and a base B electrically coupled to the host 14.

FIG. 3B shows some signal waveforms illustrating an operation of the first specific embodiment of FIG. 3A. When the SD card 10A is hot-plugged, a switch SW is closed, thereby generating a low-level voltage at an SD SWITCH pin (at t1). The low-level voltage at the SD SWITCH pin is then detected by the host 14, which then issues a negative pulse (that falls from high level to low level and then rises back to the high level again) to the base B of the BJT. The low-level voltage of the negative pulse turns off the BJT. At the end of the negative pulse (at t2), the BJT is turned on again and the power supply VP is electrically connected to the power pin VDD of the SD card 10A, thereby generating the rising voltage. After the successful ramp-up period, the controller 102 will then initialize the memory module 100 of the SD card 10A.

FIG. 3C shows some signal waveforms illustrating another operation of the first specific embodiment of FIG. 3A. An SD card 10A is hot-unplugged at time t0, thereby pulling down the voltage at the second node n2. In other words, a falling voltage is generated at the second node n2. Subsequently, when another (or the same) SD card 10A is hot-plugged, the switch SW is closed, thereby generating a low-level voltage at an SD SWITCH pin (at t1). The low-level voltage at the SD SWITCH pin is then detected by the host 14, which then issues a negative pulse to the base B of the BJT. At the end of the negative pulse (at t2), the BJT is turned on again and the power supply VP is electrically connected to the power pin VDD of the SD card 10A, thereby generating the rising voltage. After the successful ramp-up period, the controller 102 will then initialize the memory module 100 of the SD card 10A.

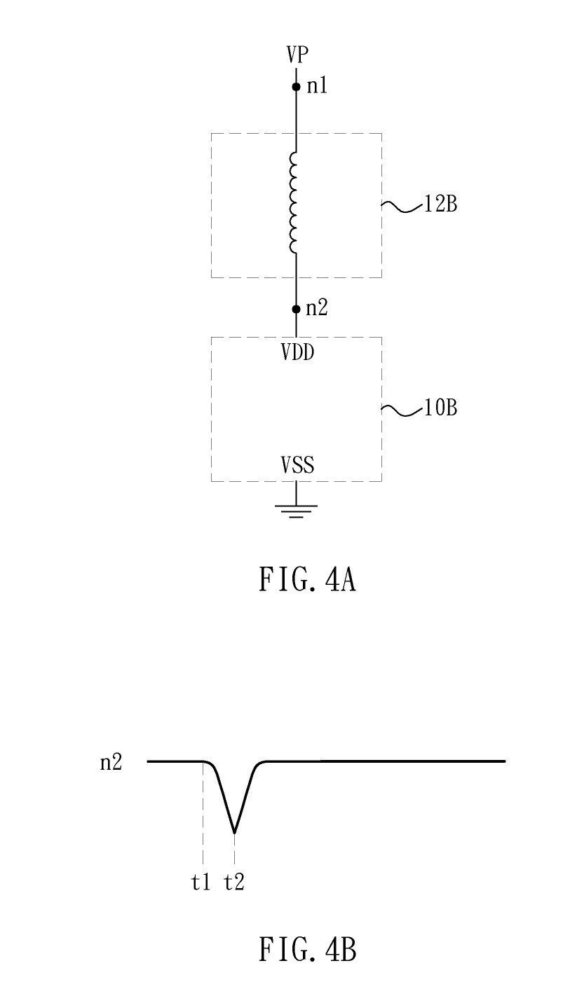

FIG. 4A illustrates a second specific embodiment showing an SD card 10B and an exemplary power-reset unit 12B. In the embodiment, the power-reset unit 12B includes a ferrite bead or an inductor. Two ends of the inductor 12B couple to the first node n1 and the second node n2 respectively.

FIG. 4B shows some signal waveforms illustrating an operation of the second specific embodiment of FIG. 4A. When the SD card 10B is hot-plugged, the inductor 12B generates a falling voltage (or voltage drop) at time t1 due to a counter electromotive force (EMF), followed by generating the rising voltage at time t2. After the successful ramp-up period, the controller 102 will then initialize the memory module 100 of the SD card 10B.

Although specific embodiments have been illustrated and described, it will be appreciated by those skilled in the art that various modifications may be made without departing from the scope of the present invention, which is intended to be limited solely by the appended claims.

What is claimed is:

1. A circuit for hot-swapping a memory card in an electronic device, comprising:
a power-reset unit having a first node electrically coupled to a power supply, and a second node electrically coupled to a power pin of the memory card;
wherein the power-reset unit is configured to generate a rising voltage at the second node without rebooting the electronic device when the memory card is hot-plugged into the electronic device.

2. The circuit of claim 1, wherein the memory card is a non-volatile memory card.

3. The circuit of claim 2, wherein the non-volatile memory card is one of the following cards: a secure digital (SD) card, a secure digital high-capacity (SDHC) card, a secure digital extended-capacity (SDXC) card, and a multimedia card (MMC).

4. The circuit of claim 1, wherein the electronic device is one of the following devices: a digital camera, a digital camcorder, a computer, a personal digital assistant (PDA), a media player, and a mobile phone.

5. The circuit of claim 1, wherein the rising voltage rises from a first voltage toward a second voltage.

6. The circuit of claim 5, wherein the memory card comprising a controller and a memory module, wherein the controller checks to determine whether the first voltage is lower than a predefined minimum voltage and the second voltage is higher than a predefined maximum voltage during a ramp-up period.

7. The circuit of claim 6, wherein the controller is configured to further initialize the memory module after the ramp-up period when the rising voltage passes the check by the controller.

8. The circuit of claim 1, wherein the power-reset unit is configured to further generate a falling voltage at the second node instantly before generating the rising voltage.

9. The circuit of claim 1, wherein the power-reset unit comprises a transistor, wherein the transistor electrically connects the power supply to the power pin of the memory card when the transistor is turned on, thereby generating the rising voltage, and the transistor is turned on by a host when the memory card is detected as being hot-plugged.

10. The circuit of claim 9, wherein the host further turns off the transistor instantly before turning on the transistor.

11. The circuit of claim 9, wherein the transistor is a bipolar junction transistor (BJT) having a collector electrically coupled to the first node, an emitter electrically coupled to the second node, and a base electrically coupled to the host.

12. The circuit of claim 8, wherein the power-reset unit comprises an inductor, wherein the inductor is configured to generate the falling voltage, followed by generating the rising voltage when the memory card is hot-plugged.

13. The circuit of claim 12, wherein the power-reset unit comprises a ferrite bead.
